(19) United States
(12) Patent Application Publication
(10) Pub. No.: US 2024/0339553 A1
(43) Pub. Date: Oct. 10, 2024

(54) APPARATUS FOR MANUFACTURING THIN FILM DEVICES

(71) Applicant: Solaires Entreprises Inc., Victoria (CA)

(72) Inventors: Alfonso Fabian de la Fuente Sanchez, Victoria (CA); Mahsid SAM, Victoria (CA); Furui TAN, Kaifeng Henan (CN); Chen DONG, Kaifeng Henan (CN); Wanlong WANG, Kaifeng Henan (CN); Yuhao SONG, Kaifeng Henan (CN)

(73) Assignee: Solaires Entreprises Inc., Victoria (CA)

(21) Appl. No.: 18/297,352

(22) Filed: Apr. 7, 2023

(51) Int. Cl. H01L 31/18; H01L 21/67; H01L 21/673; H01L 21/677

(52) U.S. Cl. CPC H01L 31/18; H01L 21/67017; H01L 21/6715; H01L 21/67326; H01L 21/67766

(57) ABSTRACT

A system for manufacturing thin-film devices is provided, the system comprising: a computing device; robotic arm or conveyor system; holder which is configured to retain a first substrate; dispenser which configured to dispense a solution onto an upper surface of the first substrate; an X-Y press, which includes a base, a vertically disposed member which is attached to the base, a horizontal arm which is moveably attached to the vertically disposed member, a vertical actuator which is configured to urge the horizontal arm up and down and is attached to the vertically disposed member, a horizontal actuator which is attached to the horizontal arm, a block which is attached to the horizontal actuator, wherein the horizontal actuator is configured to urge the block horizontally; and a dryer, wherein the robotic arm or the conveyor system, the dispenser, the X-Y press and the dryer are under control of the computing device.

### FIELD

The present technology relates to an apparatus and system for manufacturing thin film devices. More specifically it relates to an apparatus and system for manufacturing photovoltaic devices.

### BACKGROUND

Thin-film solar (photovoltaic) cells, and particularly perovskite devices, are a promising technology for sustainable and renewable energy generation since they can be flexibly installed in a variety of settings and can be much less expensive to manufacture than other types of solar cells.

Metal halide perovskite photovoltaics have undergone rapid development in the past few years, with lab efficiency of small area devices reaching 25%, which is competitive with silicon solar cells. At the same time, the pursuit of large area perovskite solar cells has attracted increasing attention in recent years. For the fabrication of large area perovskite films, industrial processes such as slot-die coating, blade coating, and roll-to-roll fabrication, may be adopted. In such processes, precise adjustments and modulation of several parameters are usually required to obtain a film with sufficiently high quality for photovoltaic applications. The dynamic coating process in these methods may require tight tolerances on the machinery involved in manufacturing. Such methods commonly fabricate a single film during each round of coating.

Thin-film devices are formed using several materials layered upon one another, by printing, coating using polymer inks, or via vacuum deposition on a substrate. A substrate in a thin-film device may include polyethylene terephthalate (PET) and indium tin oxide (ITO) as initial layers.

The relatively poor manufacturability of perovskite solar cells, when utilizing using current processes, is a significant obstacle preventing broader adoption of these cells. For example, making such processes more scalable and reproducible may improve commercial viability of perovskite solar cells.

An existing process that has been proposed is called “solution shearing” as described in Min Kyu Kim, et al. J. Mater. Chem. A, 2018, 6, 24911; Jihye Choe, et al. Solar Energy, 2019, 191, 629; Gizachew Belay Adugna, et al. ACS Appl. Mater. Interfaces, 2021, 13, 25926. In this process, a tilted blade is used to scrape liquid on a substrate.

In a related technique, blade coating relies on a sharp edge that remains in contact with the liquid solution being used to form a coating. The sharp edge may be substantially one-dimensional or at least not extending completely along the plane that is either forming the coating or is having the coating formed thereon.

The blade coating process requires precise adjustment of the distance between the blade and the surface on which the coating is being formed.

Methods like blade coating, screen printing and roll-to-roll coating are limited to producing one perovskite film in a round of coating.

What is needed is an apparatus and system for producing thin film devices. It would be preferable if two or more coated surfaces could be produced at one time. It would be preferable if the depth of the coatings could be controlled. It would be further preferable if a second and subsequent coating could be applied using the apparatus.

### SUMMARY

The present technology provides an efficient method of producing thin film devices through the use of the apparatus and system of the present technology. Two or more coated surfaces can be produced at one time. The depth of the coatings can be controlled. A second and subsequent coating can be applied.

In one embodiment, a system for manufacturing thin-film devices is provided, the system comprising: a computing device; a robotic arm or a conveyor system; a holder which is configured to retain a first substrate; a dispenser which configured to dispense a solution onto an upper surface of the first substrate; an X-Y press, which includes a base, a vertically disposed member which is attached to the base, a horizontal arm which is moveably attached to the vertically disposed member, a vertical actuator which is configured to urge the horizontal arm up and down and is attached to the vertically disposed member, a horizontal actuator which is attached to the horizontal arm, a block which is attached to the horizontal actuator, wherein the horizontal actuator is configured to urge the block horizontally; and a dryer, wherein the robotic arm or the conveyor system, the dispenser, the X-Y press and the dryer are under control of the computing device.

The system may further comprise a heater which is located downstream from the dryer and is under control of the computing device.

The system may comprise the robotic arm.

In the system, the dryer may be a gas line with a nozzle, the gas line for communication with a compressed gas source.

In the system, the compressed gas source may be a compressed nitrogen gas source.

The system may include the compressed gas source.

In the system, the heater may be one of an oven, an infrared light source or a high intensity light source.

In the system, the holder may be integral with the X-Y press.

In the system, the X-Y press may include a microprocessor which is in electronic communication with the computing device.

In another embodiment, a system is provided for manufacturing thin-film devices, the system comprising: a computing device; a robotic arm or a conveyor system; a holder which is configured to retain a first substrate; a dispenser which configured to dispense a solution onto an upper surface of the first substrate; an X-Y press, which includes a base, a vertically disposed member which is attached to the base, a horizontal arm which is moveably attached to the vertically disposed member, a vertical actuator which is configured to urge the horizontal arm up and down and is attached to the vertically disposed member, a horizontal actuator which is attached to the base, wherein the horizontal actuator is configured to urge the holder horizontally, a block which is attached to the horizontal arm and is positioned to block movement of a second substrate; and a dryer, wherein the robotic arm or the conveyor system, the dispenser, the X-Y press and the dryer are under control of the computing device.

The system may further comprise a heater which is located downstream from the dryer and is under control of the computing device.

The system may comprise the robotic arm.

In the system, the X-Y press may include a microprocessor which is in electronic communication with the computing device.

In another embodiment, an n X-Y press is provided for manufacturing thin-film devices, the X-Y press comprising a base, a holder which is attached to the base, a vertically disposed member which is attached to the base, a horizontal arm which is moveably attached to the vertically disposed member, a vertical actuator which is configured to urge the horizontal arm up and down and is attached to the vertically disposed member, a horizontal actuator which is attached to the horizontal arm, and a block which is attached to the horizontal actuator, wherein the horizontal actuator is configured to urge the block horizontally.

In the X-Y press, the vertical actuator may be a power screw system.

In the X-Y press, the horizontal actuator may be a power screw system.

The X-Y press may further comprise a microprocessor.

### BRIEF DESCRIPTION OF DRAWINGS

FIG. 1 is a schematic of the system of the present technology.

FIG. 2 is a side elevation view of the X-Y press of the system of FIG. 1.

FIG. 3 is an end elevation view of the X-Y press.

FIG. 4 is a perspective view of the holder of the system of FIG. 1.

FIGS. 5A-E show the apparatus used in coating the substrate. FIG. 5A is a side view of the holder, with a solution dispensed on the first substrate, then the second substrate being lowered on the first substrate and solution and the first and second substrates in place; FIG. 5B shows the loaded holder in the X-Y press; FIG. 5C shows the X-Y press with the vertical actuator actuated; FIG. 5D shows the X-Y press with the horizontal actuator partially actuated; and FIG. 5E shows the X-Y press with the horizontal actuator fully actuated.

FIG. 6 is a side elevation view of an alternative embodiment X-Y press.

FIG. 7 is a side elevation view of another alternative embodiment X-Y press.

FIG. 8 is a side view of an alternative system for preparing thin-film devices.

FIG. 9 is a top view of an alternative embodiment mechanism for urging the second substrate to slide over and away from the first substrate.

FIG. 10A is perspective schematic of yet another alternative embodiment in which the robotic arm is used to urge the second substrate to slide over and away from the first substrate.

FIG. 10B is a perspective schematic showing the two substrates having been separated from one another.

### DESCRIPTION

Except as otherwise expressly provided, the following rules of interpretation apply to this specification (written description and claims): (a) all words used herein shall be construed to be of such gender or number (singular or plural) as the circumstances require; (b) the singular terms “a”, “an”, and “the”, as used in the specification and the appended claims include plural references unless the context clearly dictates otherwise; (c) the antecedent term “about” applied to a recited range or value denotes an approximation within the deviation in the range or value known or expected in the art from the measurements method; (d) the words “herein”, “hereby”, “hereof”, “hereto”, “hereinbefore”, and “hereinafter”, and words of similar import, refer to this specification in its entirety and not to any particular paragraph, claim or other subdivision, unless otherwise specified; (e) descriptive headings are for convenience only and shall not control or affect the meaning or construction of any part of the specification; and (f) “or” and “any” are not exclusive and “include” and “including” are not limiting. Further, the terms “comprising,” “having,” “including,” and “containing” are to be construed as open-ended terms (i.e., meaning “including, but not limited to,”) unless otherwise noted.

Recitation of ranges of values herein are merely intended to serve as a shorthand method of referring individually to each separate value falling within the range, unless otherwise indicated herein, and each separate value is incorporated into the specification as if it were individually recited herein. Where a specific range of values is provided, it is understood that each intervening value, to the tenth of the unit of the lower limit unless the context clearly dictates otherwise, between the upper and lower limit of that range and any other stated or intervening value in that stated range, is included therein. All smaller sub ranges are also included. The upper and lower limits of these smaller ranges are also included therein, subject to any specifically excluded limit in the stated range.

Unless defined otherwise, all technical and scientific terms used herein have the same meaning as commonly understood by one of ordinary skill in the relevant art. Although any methods and materials similar or equivalent to those described herein can also be used, the acceptable methods and materials are now described.

The following disclosure relates to an apparatus and system for forming coatings, and in particularly, forming such coatings in the manufacture of photovoltaic devices. In some embodiments, the apparatus, system and processes disclosed herein may improve scalability and/or reproducibility.

The system and apparatus disclosed herein improve manufacturability, by improving ease of tuning the manufacturing process and reducing costs thereof. A uniform thickness of wet film may be formed by ensuring the two substrates contact each other uniformly.

### DEFINITIONS

Moves over—in the context of the present technology, “moves over” or “slides over” does not mean moves above or is slid above but means movement along or across.

This-film device—in the context of the present technology, a thin-film device is a substrate that has at least one thin film thereon.

### DETAILED DESCRIPTION

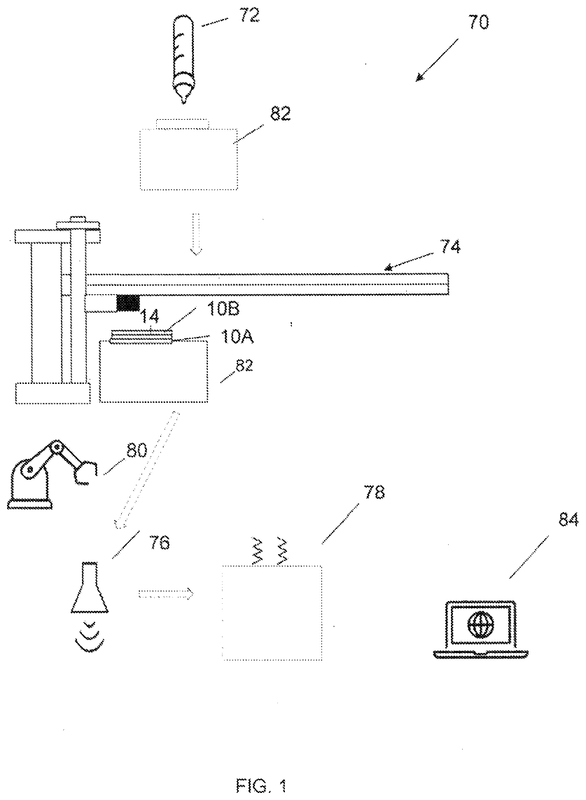

As shown in FIG. 1, the system, generally referred to as 70, includes a dispenser 72, a holder 82, an X-Y axis press 74 which is downstream from the dispenser 72, a dryer, which in one embodiment is a gas line 76, which is downstream from the X-Y axis press 74. The gas line 76 includes a nozzle and is in fluid communication with a compressed gas source, for example, but not limited to air or an inert gas such as nitrogen gas. Continuing with the description of the system 70, a heater 78 is downstream from the gas line 76 and may be an oven, a hot plate, an infrared light or high intensity visible light. A robotic arm 80 is positioned to load and unload the holder 82, then load the holder 82 onto the X-Y axis press 74, then move the coated substrate through a stream of gas from the gas line 76, then load and unload the heater 78. In an alternative embodiment, a conveyor system is positioned to accept the coated substrate and pass it through a stream of gas from the gas line 76 and through the heater 78. The system 70 is under control of a computing device 84. The substrates 10A and 10B that the thin film is formed on and the solution 14 that forms the thin film are shown on the holder 82 of the system 70. To be clear, these do not form part of the system 70.

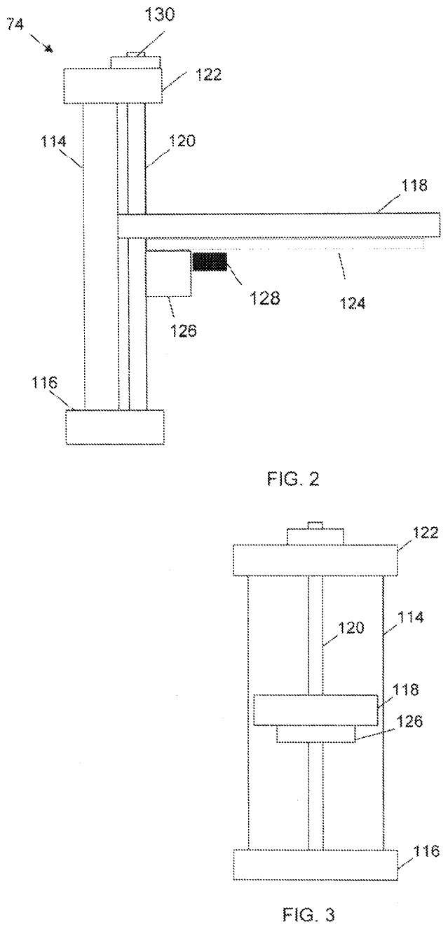

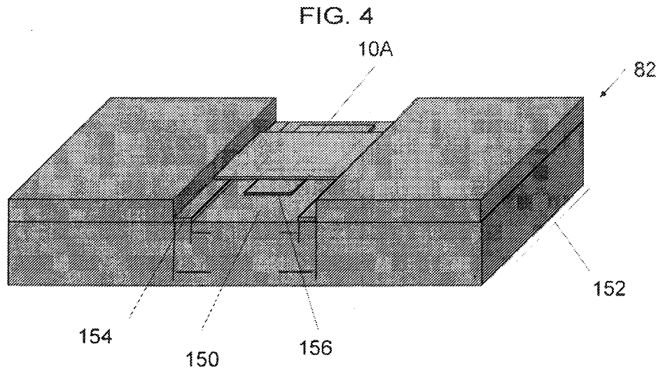

As shown in FIG. 2 and FIG. 3, the X-Y axis press 74 includes a vertical support 114, a base 116, a horizontal arm 118, a vertical actuator 120, a vertical actuator motor 122, a horizontal actuator 124, a horizontal actuator motor 126, a block 128 and a microprocessor 130. The microprocessor 130, in one embodiment, receives instructions from the computing device 84 and controls the speed at which the actuators move and the pressure that they exert. In one embodiment, the vertical actuator 120 comprises sprockets and a chain. In another embodiment, the vertical actuator 120 is a pneumatic actuator. In this embodiment, the vertical actuator motor 122 drives a pneumatic pump which is in fluid communication with the pneumatic actuator. In another embodiment, the vertical actuator 120 comprises pulleys and a belt. In another embodiment, the vertical actuator 120 comprises a rack and pinion system. In another embodiment the vertical actuator 120 is a power screw system. In one embodiment, the horizontal actuator 124 comprises sprockets and a chain. In another embodiment, the horizontal actuator 124 is a pneumatic actuator. In this embodiment, the horizontal actuator motor 126 drives a pneumatic pump, which is in fluid communication with the pneumatic actuator. In another embodiment, the horizontal actuator 124 comprises pulleys and a belt. In another embodiment, the horizontal actuator 124 comprises a rack and pinion system. In another embodiment the horizontal actuator 124 is a power screw system. The block 128 is any component that can be attached to the horizontal actuator 124 to urge the second substrate 10B horizontally. In an alternative embodiment, the holder is integrated into the X-Y press 74 and is attached to the base 116.

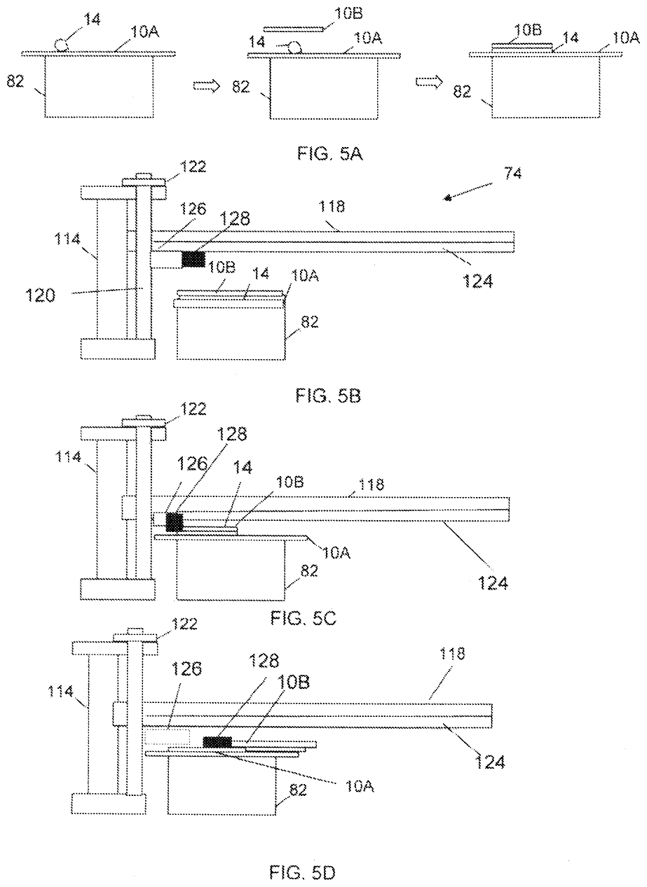

As shown in FIG. 4, the holder 82 is sized to accept the first substrate 10A. A slot 150 extends a length 152 of the holder 82 and includes two side rails 154 and a central platform 156.

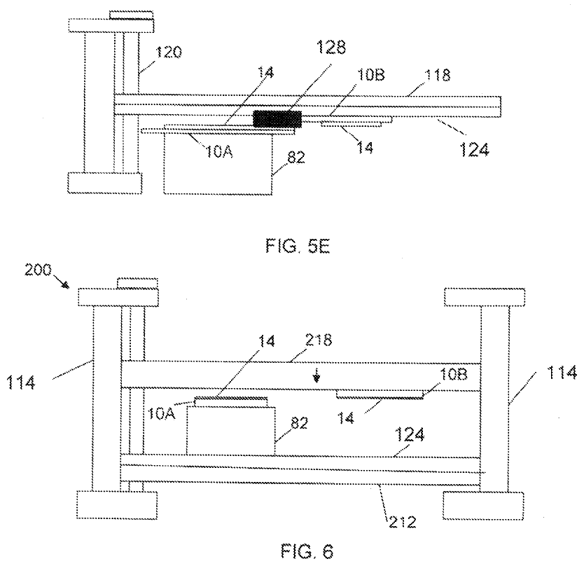

As shown in FIG. 5A, the first substrate 10A has been placed onto the holder 82 by the robotic arm 80 and the dispenser 72 has dispensed the solution 14 onto the first substrate 10A. The robotic arm 80 has lifted the second substrate 10B and is lowering it in parallel relation with the first substrate 10A. The second substrate 10B is then in place, sandwiching the solution 14 between it and the first substrate. At this time, as shown in FIG. 5B, the robotic arm 80 picks up the loaded holder 82 and places it in the X-Y press 74. As shown in FIG. 5C, the horizontal arm 118 with the horizontal actuator 124 is lowered onto the stack comprising the first substrate 10A, the second substrate 10B and the solution 14. As shown in FIG. 5D, the horizontal actuator 124 urges the block 128 along horizontally, urging the second substrate 10B to slid along the first substrate 10A. As shown in FIG. 5E the two substrates 10A, 10B have slid off each other, leaving the solution 14 coating both substrates 10A, 10B. In this embodiment, the second substrate 10B is slid over the first substrate 10A in a parallel manner. When the substrates 10A, 10B slide past one another, each surface 12A, 12B is left with a coating. In this embodiment, the first substrate 10A is static.

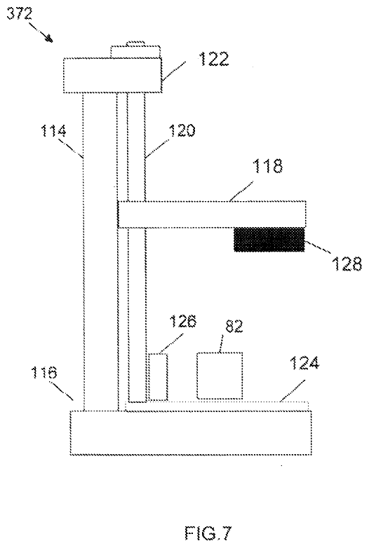

As shown in FIG. 6, an alternative embodiment X-Y axis press, generally referred to as 200, includes two vertical supports 114, and two horizontal arms 212, 218. In one embodiment the horizontal actuator 124 is located on the lower horizontal arm 212 and is configured to urge the holder 82 horizontally. This moves the first substrate 10A relative to the second substrate 10B, with the latter remaining static, as it is retained by the block 128 on the upper horizontal arm 218. In another embodiment, and the horizontal actuator 124 is located on the upper horizontal arm 218 and is configured to urge the block 128 horizontally. This moves the second substrate 10B relative to the first substrate 10A, with the latter remaining static. The remainder of the components of the X-Y axis press are as described in relation to FIGS. 2 and 3.

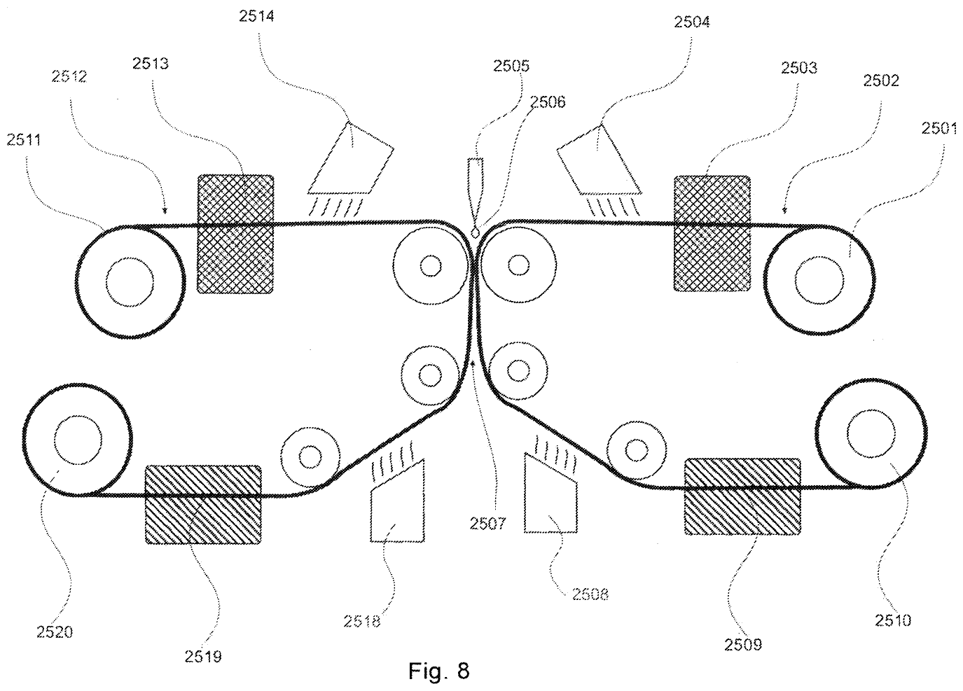

As shown in FIG. 7, an alternative embodiment X-Y axis press, generally referred to as 372 includes a vertical support 114, a base 116, a horizontal arm 118, a vertical actuator 120, a vertical actuator motor 122, a horizontal actuator 124, a horizontal actuator motor 126, and a block 128. The horizontal actuator 124 is located on the base 116 and is configured to accept the holder 82. The block 128 is attached to the underside of the horizontal arm 118 and stops the second substrate 10B from moving. The horizontal actuator 124 urges the holder 82 horizontally. This embodiment moves the first substrate 10A over the second substrate 10B, which remains stationary.

In one embodiment, the vertical actuator 120 comprises sprockets and a chain. In another embodiment, the vertical actuator 120 is a pneumatic actuator. In this embodiment, the vertical actuator motor 122 drives a pneumatic pump which is in fluid communication with the pneumatic actuator. In another embodiment, the vertical actuator 120 comprises pulleys and a belt. In another embodiment, the vertical actuator 120 comprises a rack and pinion system. In another embodiment the vertical actuator 120 is a power screw system. In one embodiment, the horizontal actuator 124 comprises sprockets and a chain. In another embodiment, the horizontal actuator 124 is a pneumatic actuator. In this embodiment, the horizontal actuator motor 126 drives a pneumatic pump, which is in fluid communication with the pneumatic actuator. In another embodiment, the horizontal actuator 124 comprises pulleys and a belt. In another embodiment, the horizontal actuator 124 comprises a rack and pinion system. In another embodiment the horizontal actuator 124 is a power screw system.

In alternative embodiment, there is a first holder on an upper conveyor belt and a second holder on a lower conveyor belt, each conveyor belt driven by a motor. The first substrate 10A and the second substrate 10B are loaded onto one or the other of the holders before the conveyor belts are started. One conveyor belt travels at a slower speed than the other conveyor belt, thus one of the substrates moves over the other substrate, then is separated from the substrate. The coated substrates continue to travel on the conveyor belts, passing the coated substrates through a stream of gas from the gas line 76 and through the heater 78, to form the thin-film device.

In all embodiments, the volume of the solution 14, the thickness of the gap between the substrates 10A, 10B and therefore the thickness of the resultant film, the speed that the substrates are slid, the drying temperature, the drying time, the heating temperature and the heating time are all controlled by the computing device 84.

The gas may be at a temperature between 18° C. and 35° C. The gas pressure is between 0.1 MPa˜0.5 MPa. Heating may be at a temperature between 20° C. and 500° C. for between ten hours and less than 1 minute. A particularly advantageous temperature and time to achieve better quality perovskite films may be about 100° C., or between 100° C. and 150° C. for between 10 and 30 minutes.

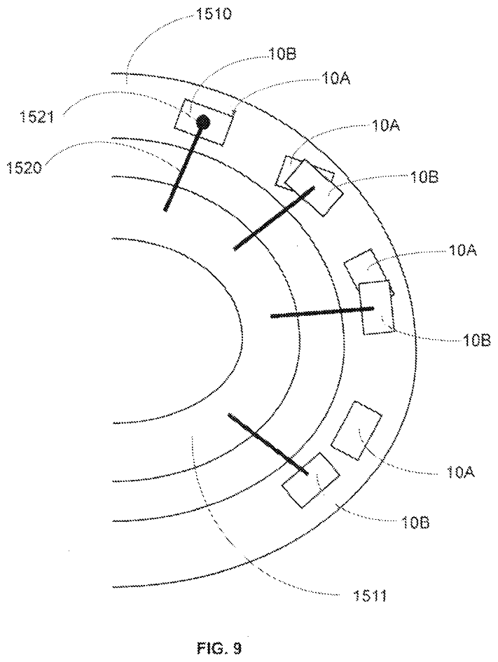

FIG. 8 is a side view of an alternative embodiment of the system where a spool (2511) of a first substrate is loaded into a feeder system, wherein the first substrate is a plastic polymer. The substrate is unspooled and the upper surface (2512) is treated with an ultraviolet plasma source (2513). It is then exposed to a stream of gas from a blower or nozzle (2514). The substrate then rotates on a cylinder, where it meets a second substrate (2501) that has gone through an ultraviolet plasma source 2503 and has been exposed to a stream of gas from a blower or nozzle 2504. A dispenser 2505 applies a solution (2506). The solution (2506) may be a precursor which can include, for example, but not limited to ink, perovskite ink, hole transport layer materials such as P3HT, SPIRO, OMeTAD, electron transport layer materials such as nickel oxide, tin oxide, top or bottom electrode materials such is indium tin oxide, titanium oxide, gold, carbon, silver. As the substrates 2501, 2511 are passing through the cylinders, they are pressed together with the solution (2506) between them. The substrates 2501, 2511 are pulled away from one another as they leave the cylinders and are now coated substrates 2510, 2520. The substrates 2510, 2520 are exposed to a stream of gas from a blower or nozzle 2508, 2518, then are exposed to heat from a heater 2509, 2519 before being spooled on their respective spools.

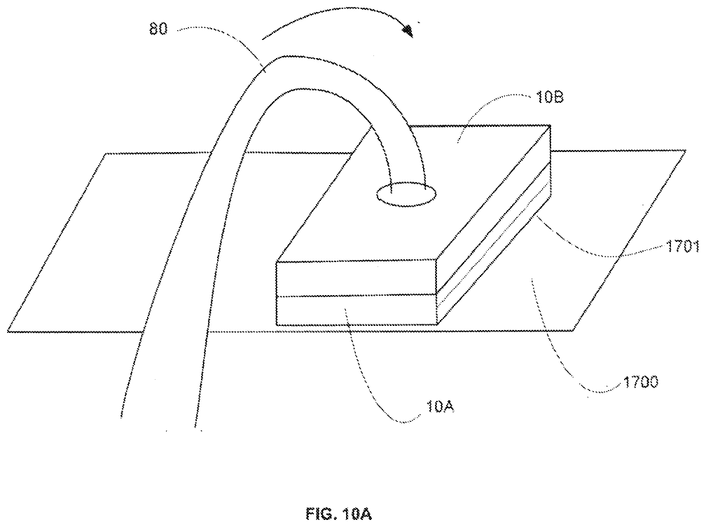

FIG. 9 shows another alternative embodiment in which two conveyor belts are used to urge the substrates 10A, 10B to slide away from one another. The robotic arm 80 loads the first substrate 10A onto the outer conveyor belt 1510, the dispenser 72 dispenses the solution 14 onto the first substrate 10A, and then the robotic arm 80 places the second substrate 10B on top of the first substrate 10A and the solution 14. The outer conveyor belt 1510 moves at a slightly slower rate than the inner conveyor belt 1511. A rigid member 1520 is attached to the inner conveyor belt 1511 and has a suction cup 1521 that is placed onto the second substrate 10B by the robotic arm 80. As can be seen, the second substrate 10B slides over the first substrate 10A, until they are clear of one another.

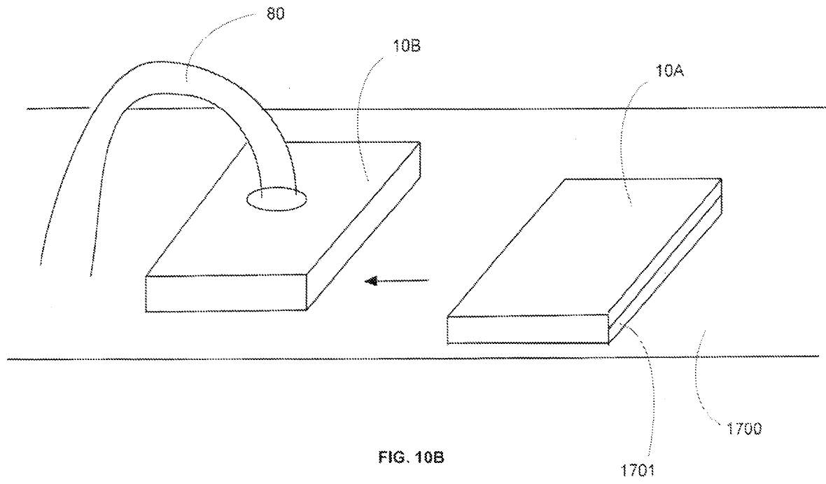

Another embodiment is shown in FIGS. 10A and 10B. The robotic arm 80 loads the first substrate 10A onto a plate 1700, the dispenser 72 dispenses the solution 14 onto the first substrate 10A, and then the robotic arm 80 places the second substrate 10B on top of the first substrate 10A and the solution 14 to provide the stack as shown in FIG. 10A. The first substrate 10A is retained on the plate 1700 with a retainer 1701. As shown in FIG. 10B, the robotic arm 80 urges the second substrate 10B to slide over the first substrate 10B, until they are clear of one another.

While example embodiments have been described in connection with what is presently considered to be an example of a possible most practical and/or suitable embodiment, it is to be understood that the descriptions are not to be limited to the disclosed embodiments, but on the contrary, is intended to cover various modifications and equivalent arrangements included within the spirit and scope of the example embodiment. Those skilled in the art will recognize or be able to ascertain using no more than routine experimentation, many equivalents to the specific example embodiments specifically described herein. Such equivalents are intended to be encompassed in the scope of the claims, if appended hereto or subsequently filed.

1. A system for manufacturing thin-film devices, the system comprising: a computing device; a robotic arm or a conveyor system; a holder which is configured to retain a first substrate; a dispenser which configured to dispense a solution onto an upper surface of the first substrate; an X-Y press, which includes a base, a vertically disposed member which is attached to the base, a horizontal arm which is moveably attached to the vertically disposed member, a vertical actuator which is configured to urge the horizontal arm up and down and is attached to the vertically disposed member, a horizontal actuator which is attached to the horizontal arm, a block which is attached to the horizontal actuator, wherein the horizontal actuator is configured to urge the block horizontally; and a dryer, wherein the robotic arm or the conveyor system, the dispenser, the X-Y press and the dryer are under control of the computing device.

2. The system of claim 1, further comprising a heater which is located downstream from the dryer and is under control of the computing device.

3. The system of claim 2, comprising the robotic arm.

4. The system of claim 3, wherein the dryer is a gas line with a nozzle, the gas line for communication with a compressed gas source.

5. The system of claim 4, wherein the compressed gas source is a compressed nitrogen gas source.

6. The system of claim 4, wherein the system includes the compressed gas source.

7. The system of claim 3, wherein the heater is one of an oven, an infrared light source or a high intensity light source.

8. The system of claim 7, wherein the holder is integral with the X-Y press.

9. The system of claim 8, wherein the X-Y press includes a microprocessor which is in electronic communication with the computing device.

10. A system for manufacturing thin-film devices, the system comprising: a computing device; a robotic arm or a conveyor system; a holder which is configured to retain a first substrate; a dispenser which configured to dispense a solution onto an upper surface of the first substrate; an X-Y press, which includes a base, a vertically disposed member which is attached to the base, a horizontal arm which is moveably attached to the vertically disposed member, a vertical actuator which is configured to urge the horizontal arm up and down and is attached to the vertically disposed member, a horizontal actuator which is attached to the base, wherein the horizontal actuator is configured to urge the holder horizontally, a block which is attached to the horizontal arm and is positioned to block movement of a second substrate; and a dryer, wherein the robotic arm or the conveyor system, the dispenser, the X-Y press and the dryer are under control of the computing device.

11. The system of claim 10, further comprising a heater which is located downstream from the dryer and is under control of the computing device.

12. The system of claim 11, comprising the robotic arm.

13. The system of claim 12, wherein the X-Y press includes a microprocessor which is in electronic communication with the computing device.

14. An X-Y press for manufacturing thin-film devices, the X-Y press comprising a base, a holder which is attached to the base, a vertically disposed member which is attached to the base, a horizontal arm which is moveably attached to the vertically disposed member, a vertical actuator which is configured to urge the horizontal arm up and down and is attached to the vertically disposed member, a horizontal actuator which is attached to the horizontal arm, and a block which is attached to the horizontal actuator, wherein the horizontal actuator is configured to urge the block horizontally.

15. The X-Y press of claim 14, wherein the vertical actuator is a power screw system.

16. The X-Y press of claim 15, wherein the horizontal actuator is a power screw system.

17. The X-Y press of claim 16, further comprising a microprocessor.
